(19) United States
(12) Patent Application Publication
(10) Pub. No.: US 2024/0266181 A1
(43) Pub. Date: Aug. 8, 2024

(54) METHOD AND APPARATUS FOR MANUFACTURING SEMICONDUCTOR CHIP WITH CHIP OUTLINE OF VARIOUS SHAPES AT WAFER LEVEL

(71) Applicant: SEOUL NATIONAL UNIVERSITY R&DB FOUNDATION, Seoul (KR)

(72) Inventors: Taehyun Kim, Seoul (KR); Kwangyeul Choi, Seoul (KR)

(21) Appl. No.: 18/435,227

(22) Filed: Feb. 7, 2024

(30) Foreign Application Priority Data
Feb. 8, 2023 (KR) 10-2023-0016908

(51) Int. Cl. H01L 21/3065; H01J 37/31; H01L 23/544

(52) U.S. Cl. CPC H01L 21/3065; H01J 37/31; H01L 23/544

(57) ABSTRACT

A method of manufacturing a semiconductor chip at a wafer level is disclosed. The method includes performing a plasma dicing process based on a predetermined shape of an outline of each of a plurality of semiconductor chips such that a dicing line along a portion of the outline extends throughout a wafer, and performing a blade dicing process such that a remaining portion of the outline of the semiconductor chip including a connection area between adjacent ones of the semiconductor chips is cut along a straight line.

### BACKGROUND

### 1. Technical Field

The present disclosure relates to a method and apparatus for manufacturing a semiconductor chip at a wafer level, and more particularly to a method and apparatus for manufacturing a semiconductor chip with a chip outline of various shapes at a wafer level.

### 2. Description of Related Art

The following content is mentioned to provide background information associated with embodiments of the present disclosure, and, of course, does not constitute the related art.

A process of dicing a wafer into portions each having a unit semiconductor chip size in manufacture of semiconductor chips at a wafer level is a final step in a semiconductor chip manufacturing process, and is an essential process. Dicing is a method of dividing a semiconductor wafer into semiconductor chips after completion of formation of transistors and formation of mutual wirings and electrodes. As representative examples of dicing, there may be blade dicing, laser dicing, plasma dicing, etc.

Among such dicing methods, blade dicing is the simplest method, but has a limitation in that only chips having a simple rectangular or parallelogram shape may be manufactured because dicing streets take only the form of a straight line.

Laser dicing exhibits degraded productivity for a wafer having a thickness of 100 μm or more, and has a limitation on kinds of applicable devices due to high heat generated during cutting. Furthermore, damage may be applied to a wafer surface due to physical contact of heat or a laser and, as such, there is a possibility of occurrence of grooving. In order to avoid such a phenomenon, surface coating is required.

Plasma dicing requires deep Si etching or plasma-based etching similar to deep Si etching. For this reason, an additional process of depositing, over the entire surface of a wafer, a thick protective layer for protecting a chip area not to be cut during etching may be required.

However, in the case of a device disabling stacking of an additional protective layer on the entire surface of the wafer due to a structure thereof, for example, in the case of an ion trap device configured to trap ions, application of such a method thereto may be difficult.

In order to avoid the above-mentioned problems, a plasma dicing process may be applied before execution of other processes. In this case, however, processes should be repeated on a chip basis after completion of dicing. Otherwise, for execution of processes on a wafer basis, a procedure of leaving behind a thin beam configured to maintain connection of each portion of a wafer to the remaining portion of the wafer and breaking the beam in a final step should be carried out.

However, when such a thin beam is broken, small fragments generated due to breakage of the thin beam may damage surfaces of chips or may be attached between chips. For this reason, there is a high possibility that the fragments function as a factor interfering a function of chips. As a result, device yield may be degraded.

To this end, a method of more effectively dicing a wafer into semiconductor chips at a wafer level is needed.

The above matters disclosed in this section are technical information possessed by the inventor, for derivation of the present disclosure, or acquired in a procedure of deriving the present disclosure, and should not be taken as an acknowledgement or any form of suggestion that the matters form the related art already known to a person skilled in the art.

### PRIOR ART LITERATURE

### Patent Documents

Patent Document 0001: Korean Unexamined Patent Publication No. KR10-2015-0129962 (issued on Nov. 23, 2015)

### SUMMARY OF THE INVENTION

An aspect of the present disclosure is to provide a method of manufacturing a semiconductor chip having a chip outline of various shapes without being limited to a simple straight-line shape in accordance with an application form of the semiconductor chip.

Another aspect of the present disclosure is to provide a method of manufacturing a semiconductor chip at a wafer level, which enables the semiconductor chip to minimize laser scattering while effectively trapping ions when the semiconductor chip is implemented as an ion trap chip configured to trap ions.

However, such aspects are illustrative, without limiting the scope of the present disclosure.

In an aspect of the present disclosure, there is provided a method of manufacturing a semiconductor chip at a wafer level, including performing a plasma dicing process based on a predetermined shape of an outline of each of a plurality of semiconductor chips such that a dicing line along a portion of the outline extends throughout a wafer, and performing a blade dicing process such that a remaining portion of the outline of the semiconductor chip including a connection area between adjacent ones of the semiconductor chips is cut along a straight line.

The method may further include performing one or more processes in which a gas for cooling is not mixed with plasma, after the performing a plasma dicing process.

The performing one or more processes may include performing at least one of a deposition process or a patterning process.

The method may further include predetermining the outline portion of each of the plurality of semiconductor chips which is a dicing target.

The predetermined outline portion of each of the plurality of semiconductor chips may include at least one of a curved line or a bent line.

Each of the plurality of semiconductor chips may be an ion trap chip configured to trap ions.

The performing a plasma dicing process may include dicing the outline portion of each of the ion trap chips to reduce or remove interference caused by a laser when ions are trapped at an upper surface of the ion trap chip.

The semiconductor chip may be a microelectromechanical system (MEMS) chip.

In another aspect of the present disclosure, there is provided a semiconductor chip manufactured by the method as described above.

In another aspect of the present disclosure, there is provided an apparatus for manufacturing a semiconductor chip at a wafer level, including a controller configured to determine a shape of an outline of a semiconductor chip, a plasma dicing module configured to perform a plasma dicing process in which a dicing line along a portion of an outline of each of a plurality of semiconductor chips extends throughout a wafer, based on the outline shape of the semiconductor chip, and a blade dicing module configured to perform a blade dicing process in which a remaining portion of the outline of each of the plurality of semiconductor chips including a connection area between adjacent ones of the semiconductor chips is cut along a straight line.

The controller may be configured to predetermine the portion of the outline of each of the plurality of semiconductor chips which is a dicing target.

The predetermined outline portion of each of the plurality of semiconductor chips may include at least one of a curved line or a bent line.

Each of the plurality of semiconductor chips may be an ion trap chip configured to trap ions.

The plasma dicing module may be configured to dice the outline portion of each of the plurality of ion trap chips in order to reduce or remove interference caused by a laser when ions are trapped at an upper surface of the ion trap chip.

### BRIEF DESCRIPTION OF THE DRAWINGS

The above and other aspects, features, and advantages of the present disclosure will become apparent from the detailed description of the following aspects in conjunction with the accompanying drawings, in which:

FIGS. 1(a) to 1(f) are views briefly explaining a semiconductor chip manufacturing procedure according to an embodiment of the present disclosure;

FIG. 2 is a block diagram showing a configuration of an apparatus for manufacturing a semiconductor chip at a wafer level in accordance with an embodiment of the present disclosure;

FIG. 3 is a flowchart showing a method of manufacturing a semiconductor chip at a wafer level in accordance with an embodiment of the present disclosure;

FIG. 4 is a view explaining a semiconductor chip having a first shape according to an embodiment of the present disclosure;

FIG. 5 is a view explaining a semiconductor chip having a second shape according to an embodiment of the present disclosure;

FIGS. 6(a) to 7 are views explaining technical advantages obtained through formation of a chip outline having various shapes; and

FIGS. 8(a) to 9 are views explaining a semiconductor chip manufactured in accordance with an embodiment of the present disclosure.

### DETAILED DESCRIPTION

Advantages and features of the present disclosure and methods for achieving them will become apparent from the descriptions of aspects herein below with reference to the accompanying drawings. However, the present disclosure is not limited to the aspects disclosed herein but may be implemented in various different forms. The aspects are provided to make the description of the present disclosure thorough and to fully convey the scope of the present disclosure to those skilled in the art. It is to be noted that the scope of the present disclosure is defined only by the claims.

The shapes, sizes, ratios, angles, the number of elements given in the drawings are merely exemplary, and thus, the present disclosure is not limited to the illustrated details. Like reference numerals designate like elements throughout the specification.

In relation to describing the present disclosure, when the detailed description of the relevant known technology is determined to unnecessarily obscure the gist of the present disclosure, the detailed description may be omitted.

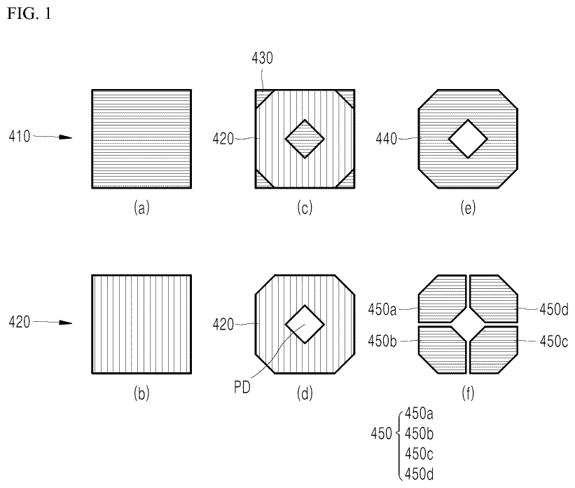

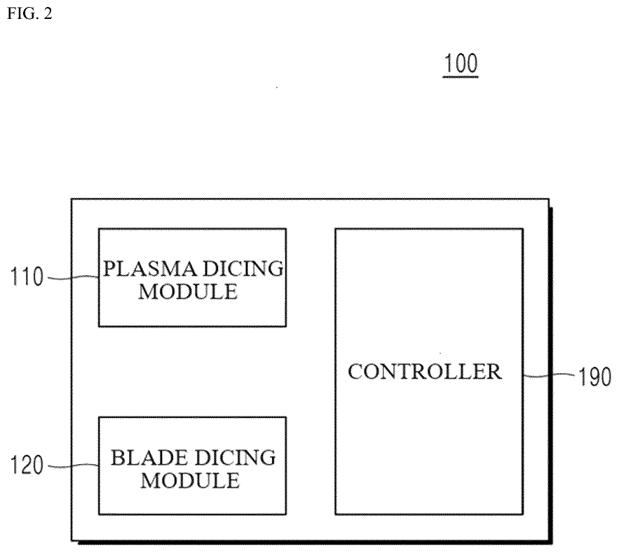

FIGS. 1(a) to 1(f) are views briefly explaining a semiconductor chip manufacturing procedure according to an embodiment of the present disclosure. FIG. 2 is a block diagram showing a configuration of an apparatus 100 for manufacturing a semiconductor chip at a wafer level in accordance with an embodiment of the present disclosure.

First, a wafer 410 may be disposed at a process execution position in the semiconductor chip manufacturing apparatus 100 (FIG. 1(a)).

Here, the wafer 410 may be an Si wafer to be subjected to plasma dicing, but embodiments of the present disclosure are not limited thereto. In addition, the wafer 410 represents a portion of an entire wafer. The entire wafer may basically have a circular shape and, as such, may have various diameters.

Next, a coating 420 of photoresist (PR) may be formed on the wafer 410 (FIG. 1(b)).

In this case, when the wafer 410 has a thickness of about 500 μm, a photoresist (PR) capable of withstanding etching (for example, Si etching) of 500 μm may be used (for example, a photoresist (PR), AZ4330, may be coated up to a thickness of about 3.9 μm). However, in accordance with an embodiment, the thickness of the wafer 410 may be varied, and a usable example of the photoresist (PR) may also be varied in accordance with a thickness of the wafer 410.

Thereafter, a pattern 430 may be produced through light exposure and development (FIG. 1(c)).

In this case, a pattern corresponding to a portion of the outline of a diced wafer piece may be developed using exposure equipment, and development may be carried out in a positive or negative manner.

Subsequently, the wafer 410 may be diced through plasma dicing (for example, including Si etching) such that a dicing line extends throughout the wafer (FIG. 1(d)).

That is, plasma dicing may be carried out through repetition of polymer deposition, removal of polymer from a bottom surface, and Si etching. In accordance with such plasma dicing, the wafer 410 may be diced such that a dicing line extends therethrough. In this case, etched areas having various shapes may be formed to extend through a central portion PD and edge portions of the wafer 410. At the central portion PD, an etched area having a diamond shape may be formed. In accordance with etched areas at the edge portions of the wafer 410, the etched wafer 410 may form an octagonal shape. When blade dicing is used, it may be difficult to form such a shape.

Thereafter, the photoresist (PR) coating 420 may be removed (FIG. 1(e)).

In this case, the photoresist (PR) used in etching may be removed using a stripper solution. An uppermost layer 440 of the wafer 410 may include a layer (for example, an oxide film layer, an electrode layer, or the like), etc. formed through one or more processes, but embodiments of the present disclosure are not limited thereto.

After execution of the above-described process, a deposition process, an etching process, a photo process, etc. may be carried out. However, various processes may be carried out so long as a gas (a gas for cooling (He)) is not mixed with plasma.

In an embodiment, blade dicing may first be performed, and plasma dicing may then be performed.

Finally, wafer pieces 540 (450a to 450d) may be manufactured through blade dicing on a straight-line basis (FIG. 1(f)).

Areas BD subjected to blade dicing may extend throughout the wafer 410, and resultant wafer pieces 450 (450a to 450d) may be formed to have a hexagonal shape. Each wafer piece 450 may include a plurality of devices, and may be a device taking the form of a package. Of course, embodiments of the present disclosure are not limited to the above-described conditions.

As the primary plasma dicing process and the secondary blade dicing process are carried out by the wafer-level semiconductor chip manufacturing apparatus 100 according to the embodiment of the present disclosure, various chip outlines may be formed.

Referring to FIG. 2, the wafer-level semiconductor chip manufacturing apparatus 100 may include a plasma dicing module 110, a blade dicing module 120, and a controller 190 configured to determine an outline shape of a semiconductor chip. Of course, the configurations shown in FIG. 2 are not essential in configuring the semiconductor chip manufacturing apparatus 100, and the semiconductor chip manufacturing apparatus 100 disclosed in the present disclosure may include a greater or smaller number of configurations than that of the case shown in FIG. 2.

First, the controller 190 may determine an outline shape of a semiconductor chip. The controller 190 may determine the outline shape in accordance with an intention of a semiconductor chip designer. The outline shape may be a quadrangular shape or a shape more complex than the quadrangular shape (various shapes including a pentagonal shape, a shape having a greater number of sides than that of the pentagonal shape, a shape including a curved line/bent line, etc.)

The plasma dicing module 110 is a module configured to perform plasma dicing, and may perform precise dicing at a wafer level.

In this case, the plasma dicing module 110 may perform dicing through an etching process while using a chemical reaction gas as a raw material, but embodiments of the present disclosure are not limited thereto.

The blade dicing module 120 is a module configured to perform dicing on a straight-line basis and, as such, may perform final dicing at a wafer level.

The blade dicing module 120 may perform dicing using a blade. Dicing may be carried out as a wafer moves under the blade in a state in which the blade is driven. In this case, a driving speed of the blade and a movement speed of the wafer may be appropriately set to obtain an excellent yield.

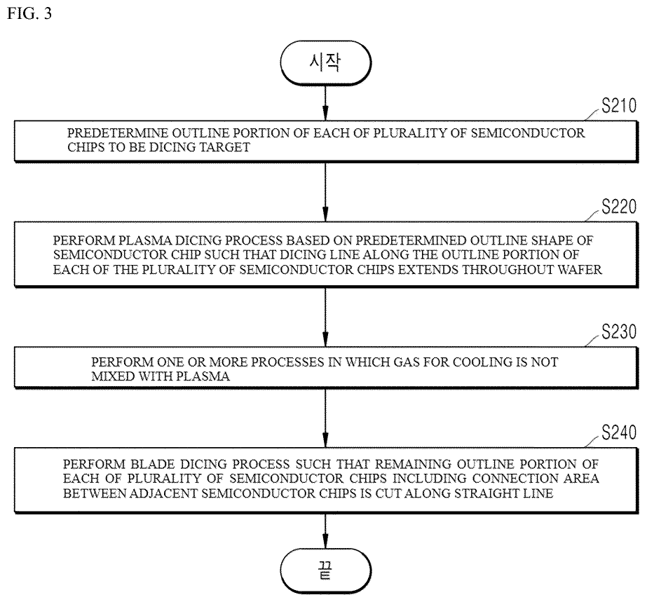

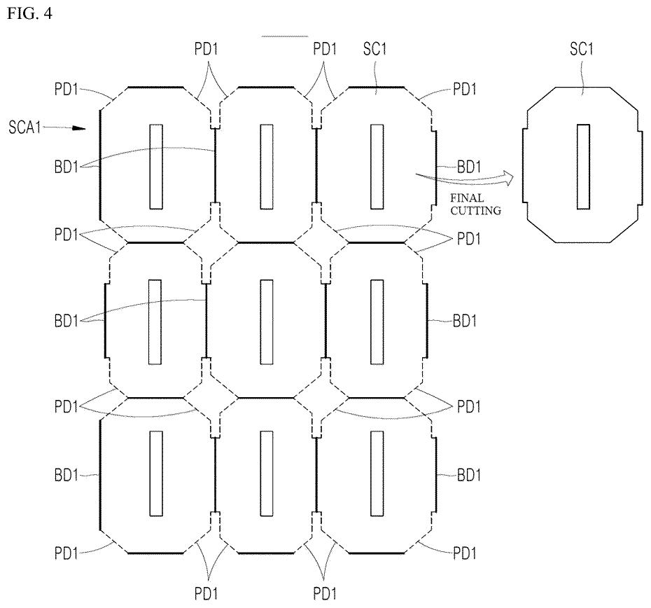

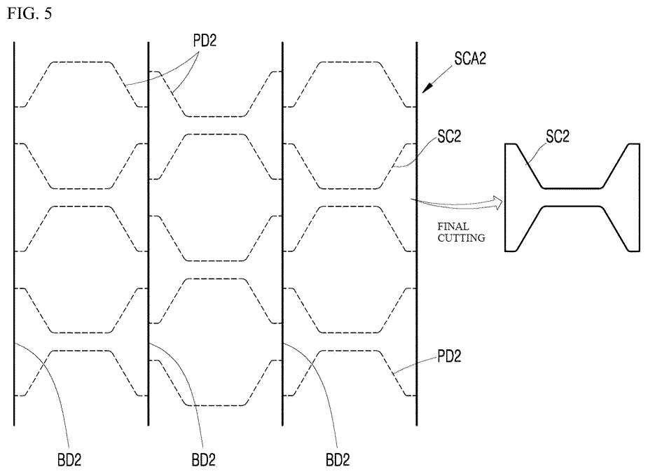

FIG. 3 is a flowchart showing a method of manufacturing a semiconductor chip at a wafer level in accordance with an embodiment of the present disclosure. FIG. 4 is a view explaining a semiconductor chip having a first shape according to an embodiment of the present disclosure. FIG. 5 is a view explaining a semiconductor chip having a second shape according to an embodiment of the present disclosure. FIGS. 4 and 5 will be referred to when matters associated therewith are described in explaining the method of FIG. 3.

First, a portion of an outline to be diced in each of a plurality of semiconductor chips may be determined (S210).

All areas to be diced in each of the plurality of semiconductor chips may be determined by a chip designer, and a portion of an outline to be diced may be primarily determined. Here, the outline portion may be an outline to be diced through plasma dicing. The controller 190 may determine an outline shape of each semiconductor chip. The controller 190 may determine the outline portion of the semiconductor chip to be diced, taking into consideration disposition, application example, etc. of devices in the semiconductor chip.

In accordance with a selective or additional embodiment, when an ion trap chip is manufactured, the controller 190 of the semiconductor chip manufacturing apparatus 100 may set a figure/shape/size or the like of the semiconductor chip at an ion trap position, based on the ion trap position on an upper surface of the semiconductor chip, a laser transmission position/direction, etc.

Based on the determined semiconductor chip outline shape, the plasma dicing module 110 may perform a plasma dicing process in which a portion of the outline of each of the plurality of semiconductor chips is diced such that a dicing line along the outline portion extends throughout a wafer (S220) (plasma dicing process step). In this case, the dicing line may extend throughout the wafer even when the wafer has a thickness of 100 μm or more.

Referring to FIG. 4, in the primary dicing process step S220, the plasma dicing module 110 of the semiconductor chip manufacturing apparatus 100 may perform plasma dicing at a wafer level in order to form a complex shape PD1 rather than a simple straight-line shape. The plasma dicing module 110 may perform dicing to form a shape such as a bent line shape, a curved line shape, etc. Accordingly, it may be possible to eliminate a limitation of blade dicing in which dicing is carried out only along a straight line.

In particular, when a semiconductor chip SC1 to be produced is an ion trap chip, it may be possible to minimize laser scattering during ion trap in accordance with implementation of the semiconductor chip SC1 to have an octagonal shape.

Referring to FIG. 5, the plasma dicing module 110 of the semiconductor chip manufacturing apparatus 100 may perform plasma dicing at a wafer level in the primary dicing process step S220 in order to form a complex shape PD2 rather than a simple straight-line shape. The plasma dicing module 110 may perform dicing to form a bent line, a curved line, etc. and, as such, it may be possible to eliminate a limitation of blade dicing in which dicing is carried out only along a straight line.

In particular, when a semiconductor chip SC2 to be produced has a bow tie shape, it may be possible to minimize laser scattering when ions are trapped.

Referring to FIGS. 4 and 5, the plasma dicing module 110 may perform dicing to form various surface shapes.

After execution of the plasma dicing process step S220, the blade dicing module 120 may perform one or more processes in which a gas for cooling is not mixed with plasma (S230).

The processes may include at least one of a deposition process or a patterning process. The patterning process may include a PR coating process, a light exposure process, a development process, etc. Of course, embodiments of the present disclosure are not limited to the above-described conditions.

After execution of step S230, the blade dicing module 120 may cut a remaining outline of each of the plurality of semiconductor chips including a connection area between adjacent ones the semiconductor chips, along a straight line (S240).

Referring to FIG. 4, the blade dicing module 120 secondarily performs dicing (BD1) on a straight-line basis. In this case, the connection area between the adjacent semiconductor chips, a quadrangular area circumscribed about the semiconductor chips, etc. may be diced and, as such, octagonal semiconductor chips SC1 may be finally manufactured.

Referring to FIG. 5, the blade dicing module 120 performs dicing (BD2) along a straight line. In this case, the connection area between the adjacent semiconductor chips, an area circumscribed about the semiconductor chips (for example, a quadrangular area), etc. may be diced and, as such, octagonal semiconductor chips SC2 having a shape similar to a bow tie shape may be finally manufactured.

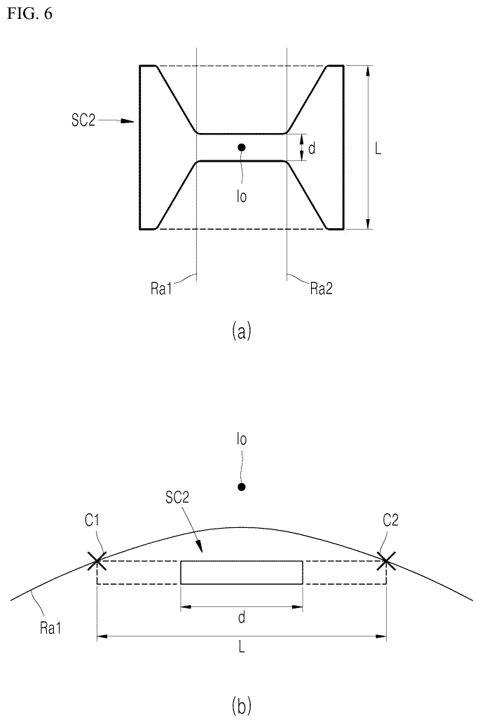

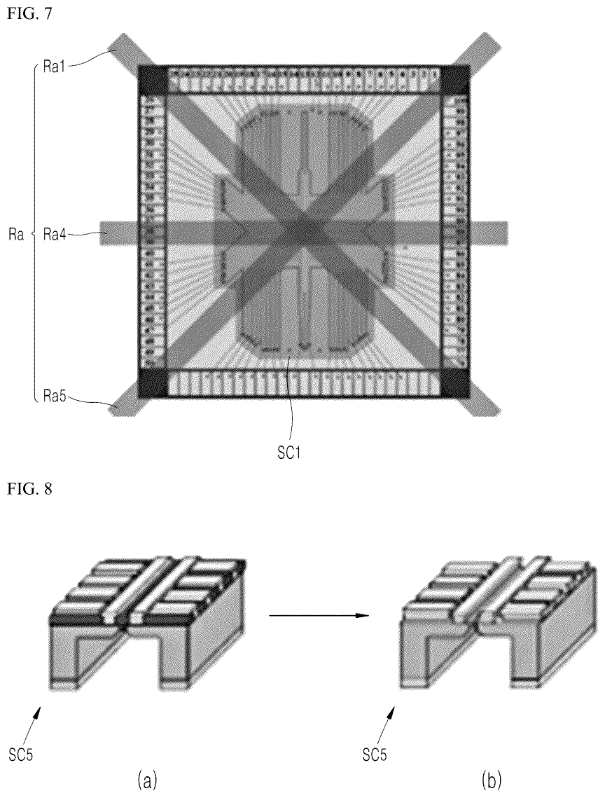

FIGS. 6(a) to 7 are views explaining technical advantages obtained through formation of a chip outline having various shapes. FIGS. 6(a) and 6(b) are views explaining the semiconductor chip SC2 shown in FIG. 5. FIG. 7 is a view explaining the semiconductor chip SC1 shown in FIG. 4.

Referring to FIGS. 6(a) and 6(b), the semiconductor chip SC2 may be applied to a quantum computer or the like, and may be implemented as an ion trap chip configured to trap ions by an electromagnetic field. In particular, the semiconductor chip SC2 may be implemented as a microelectromechanical system (MEMS) chip, but embodiments of the present disclosure are not limited thereto.

An ion Jo may be trapped at an upper surface of the ion trap chip. In this case, when lasers Ra1 and Ra2 are transmitted through the ion trap chip, scattering of the lasers Ra1 and Ra2 may be minimized because a chip width d of the ion trap chip is smaller than an outside chip width L of the ion trap chip.

When it is assumed that the chip width at a point where an ion is trapped is great (for example, “L”), a laser, for example, the laser Ra1, may be brought into contact with certain portions of the ion trap chip, for example, portions C1 and C2. As a result, a scattering phenomenon may occur.

Referring to FIG. 7, the outline of the semiconductor chip SC1 may not have a simple rectangular or parallelogram shape, but may have an octagonal shape, in order to prevent interference caused by lasers Ra3, Ra4, and Ra5.

In addition, the semiconductor chip SC1 may be designed to maximally reduce a path along which a laser moves over the chip and to minimize laser scattering.

In addition, in the semiconductor chip SC1, bonding regions of wires connected to a ceramic pin grid array (CPGA) may be displaced in order to prevent a possibility that a laser is brought into contact with the wires during irradiation thereof.

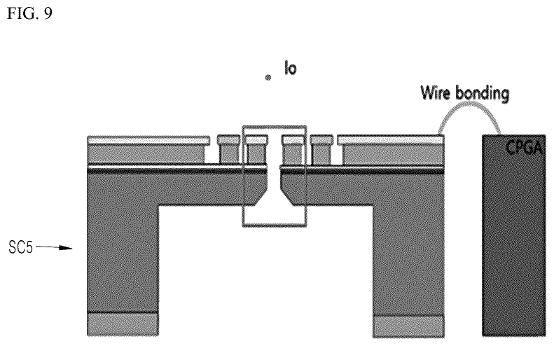

FIGS. 8(a) to 9 are views explaining a semiconductor chip manufactured in accordance with an embodiment of the present disclosure.

The semiconductor chip shown in FIGS. 8(a) to 9, that is, a semiconductor chip SC5, may be an ion trap chip, may include a sacrificial layer (for formation of a complex structure using polyimide (PI)), and may be implemented as a MEMS chip. The semiconductor chip SC5 may include a comb drive resonator, a comb drive actuator, etc. without a variation in structure. In addition, a metal may be deposited on a surface of the semiconductor chip SC5 under the condition that the structure of the semiconductor chip SC5 is fixed and, as such, may be used as an electrode.

For manufacture of the semiconductor chip SC5, processes of SiO₂ deposition, SiO₂ dry-etching, Al deposition, Al dry-etching, SiNₓ deposition, SiNₓ dry-etching, and Si-based plasma dicing, etc. may be included, but embodiments of the present disclosure are not limited thereto.

Referring to FIG. 9, a loading slot inclination (a bottom portion of a red quadrangular structure) may be added to the semiconductor chip SC5 using KOH and, as such, the semiconductor chip SC5 may be implemented as a structure capable of minimizing an amount of Si exposed to trapped ions.

Plasma dicing may be performed at a state of FIG. 8(a), and blade dicing may be performed between states of FIGS. 8(a) and 8(b). However, embodiments of the present disclosure are not limited to the above-described conditions.

In accordance with an embodiment, in the above-described wafer-level semiconductor chip manufacturing method, a plasma dicing process may be performed several times in a divided manner. In a first plasma dicing process, the plasma dicing module 110 may dice a portion of an outline, which is a target to be subjected to plasma dicing, such that a dicing line incompletely extending through a wafer is formed. For example, when the wafer has a thickness of 500 μm, the plasma dicing module 110 may etch the wafer up to 400 μm.

At a predetermined time after execution of the first plasma dicing process, the blade dicing module 120 may dice the remaining outline portion other than the outline portion which is the plasma dicing target, along a straight line.

Thereafter, the plasma dicing module 110 performs a second plasma dicing process for the outline portion which is the plasma dicing target and, as such, a semiconductor chip may be manufactured.

As apparent from the above description, in various embodiments of the present disclosure, a semiconductor chip having a chip outline of various shapes without being limited to a simple straight-line shape in accordance with a use form thereof. In addition, a semiconductor chip capable of minimizing laser scattering while effectively trapping ions when the semiconductor chip is applied to an ion trap chip configured to trap ions may be manufactured at a wafer level. Various manufacturing processes may be added between primary plasma dicing and secondary plasma dicing and, as such, a manufacturing process route may be diversified, an enhancement in manufacture efficiency may be achieved, and consumer needs may be satisfied.

While the present disclosure has been explained in relation to its embodiments, it is to be understood that various modifications thereof will become apparent to those skilled in the art upon reading the specification. Therefore, it is to be understood that the present disclosure is intended to cover such modifications as fall within the scope of the appended claims.

1. A method of manufacturing a semiconductor chip at a wafer level, comprising:
performing a plasma dicing process based on a predetermined shape of an outline of each of a plurality of semiconductor chips such that a dicing line along a portion of the outline extends throughout a wafer; and
performing a blade dicing process such that a remaining portion of the outline of the semiconductor chip comprising a connection area between adjacent ones of the semiconductor chips is cut along a straight line.

2. The method according to claim 1, further comprising:
performing one or more processes in which a gas for cooling is not mixed with plasma, after the performing a plasma dicing process.

3. The method according to claim 2, wherein the performing one or more processes comprises performing at least one of a deposition process or a patterning process.

4. The method according to claim 1, further comprising:
predetermining the outline portion of each of the plurality of semiconductor chips which is a dicing target.

5. The method according to claim 4, wherein the predetermined outline portion of each of the plurality of semiconductor chips comprises at least one of a curved line or a bent line.

6. The method according to claim 5, wherein each of the plurality of semiconductor chips is an ion trap chip configured to trap ions.

7. The method according to claim 6, wherein the performing a plasma dicing process comprises dicing the outline portion of each of the ion trap chips to reduce or remove scattering of a laser when ions are trapped at an upper surface of the ion trap chip.

8. The method according to claim 1, wherein the semiconductor chip is a microelectromechanical system (MEMS) chip.

9. A semiconductor chip manufactured by the method according to claim 1.

10. An apparatus for manufacturing a semiconductor chip at a wafer level, comprising:
a controller configured to determine a shape of an outline of a semiconductor chip;
a plasma dicing module configured to perform a plasma dicing process in which a dicing line along a portion of an outline of each of a plurality of semiconductor chips extends throughout a wafer, based on the outline shape of the semiconductor chip; and
a blade dicing module configured to perform a blade dicing process in which a remaining portion of the outline of each of the plurality of semiconductor chips comprising a connection area between adjacent ones of the semiconductor chips is cut along a straight line.

11. The apparatus according to claim 10, wherein the controller is configured to predetermine the portion of the outline of each of the plurality of semiconductor chips which is a dicing target.

12. The apparatus according to claim 11, wherein the predetermined outline portion of each of the plurality of semiconductor chips comprises at least one of a curved line or a bent line.

13. The apparatus according to claim 12, wherein each of the plurality of semiconductor chips is an ion trap chip configured to trap ions.

14. The apparatus according to claim 13, wherein the plasma dicing module is configured to dice the outline portion of each of the plurality of ion trap chips in order to reduce or remove interference caused by a laser when ions are trapped at an upper surface of the ion trap chip.

15. The apparatus according to claim 12, wherein the semiconductor chip is a microelectromechanical system (MEMS) chip.
